(19) United States
(12) Patent Application Publication
(10) Pub. No.: US 2005/0026416 A1
(43) Pub. Date: Feb. 3, 2005

(54) ENCAPSULATED PIN STRUCTURE FOR IMPROVED RELIABILITY OF WAFER

(75) Inventors: Tien-Jen Cheng, Bedford, NY (US); David E. Eichstadt, North Salem, NY (US); Jonathan H. Griffith, LaGrangeville, NY (US); Randolph F. Knarr, Goldens Bridge, NY (US); Kevin S. Petrarca, Newburgh, NY (US); Roger A. Quon, Rhinebeck, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, ARMONK, NY (US)

(21) Appl. No.: 10/604,578

(22) Filed: Jul. 31, 2003

(51) Int. Cl. H01L 21/44

(52) U.S. Cl. 438/613

(57) ABSTRACT

A solder bump for bonding an electronic device to a substrate or another structure is formed by plating a high aspect ratio copper pin on a supporting structure, encapsulating the pin in a barrier material, plating a solder on the barrier material and then reflowing the solder.

### BACKGROUND OF INVENTION

### TECHNICAL FIELD

The field of the invention is that of integrated circuit packaging, in particular flip chip technology.

Printed circuit boards (also referred to as printed wiring boards), hereinafter simply referred to as a “PCB”, have become ubiquitous. PCB's typically are in the form of a dielectric substrate (such as for example an organic resin reinforced by fibers) which is cladded on one or both sides with a conductor (such as for example copper). The dielectric substrate is provided with a predetermined pattern of perforations for making connections with wiring and electrical devices, wherein the conductor is patterned so as to provide a predetermined electrical routing between the perforations so that the wiring and electrical devices are functionally interconnected.

During the 1960's IBM Corporation developed an alternative technology to hardwiring all interfaces, referred to commonly as “controlled collapse chip connection” or simply “C4”. According to this technology, a chip is attached to the electronics of a PCB by matched contact of bumps on the chip with interface pads on the PCB. A chip provided with a series of bumps for C4 is referred to as a “flip chip”. The bumps have been typically a solder alloy (for example lead 97%, tin 3%) deposited by a bump mask onto wettable bump pads, and the interface pads on the PCB are also wettable whereby electrical and mechanical interconnections are formed simultaneously by reflowing of the bumps. Advantages of this technology include the reflowing compensating for chip-to-substrate misalignment incurred during chip placement and for the bumps to absorb stress.

The bumps are deposited onto the bump pads using a bump mask which is then removed. At this stage, the bumps resemble a truncated cone, being widest at the bump pad. Thereafter, a non; oxidizing reflow process is applied to the bumps, whereafter the bumps are convexly shaped, resembling truncated egg-shapes.

While C4 technology may be used to provide bumps on the chip, as was detailed hereinabove, it is to be noted that C4 technology may be equally well practiced to provide bumps on the PCB, wherein the chip is provided with the interface pads. Further, C4 technology may be practiced for attaching electronic structures other than chips; e.g. small PCBs attached to larger ones, etc.

As dimensions shrink, it is required to reduce the pitch and pack more contacts within a given area. That, in turn, reduces the permissible spacing between C4 bumps and increases the chances of shorting adjacent bumps. Various attempts have been made to increase contact density.

US2002-0179689 A1: Pillar Connections for Semiconductor Chips and Method of Manufacture (Inventor: F. Tung) shows a copper pillar capped by a eutectic solder. The structure is formed by sequentially plating stacks of metallurgy The copper pin is exposed to and is in contact with the solder, thereby permitting the formation of undesirable Cu—Sn intermetallic compounds.

U.S. Pat. No. 5,773,889: Wire Interconnect Structures for Connecting an Integrated Circuit to a Substrate (Inventor D. Love, et al.) shows the fabrication of a pin-like structure of copper partially by a shell of nickel. Devices are connected to substrates by fillets of solder at both bases of the pin structure. This structure is complex, requiring the use of three masks.

### SUMMARY OF INVENTION

The invention relates to a method of making fine-pitch conductive pads (also referred to as bumps) for flip-chip bonding.

A feature of the invention is a supporting pin plated directly to a seed layer.

Another feature of the invention is plating the pin through an aperture defined by lithography in a layer of photoreresist.

Another feature of the invention is selective etching of the seed stack selective to the solder, removing the seed stack without attacking the solder.

### BRIEF DESCRIPTION OF DRAWINGS

FIG. 1 shows a top area of an integrated circuit with unpatterned layers.

FIG. 2 shows the same area after patterning a layer of photoresist.

FIG. 3 shows the result of etching through the seed layers.

FIG. 4 shows the structure after stripping the photoresist.

FIG. 5 shows the result of plating a copper pin.

FIG. 6 shows the result of plating a barrier metal on the copper.

FIG. 7 shows the result of plating a layer of solder, before reflow.

FIG. 8 shows the result of etching the adhesion layer.

FIG. 9 shows the result of reflowing the solder.

FIG. 10 shows a step in an alternative embodiment.

### DETAILED DESCRIPTION

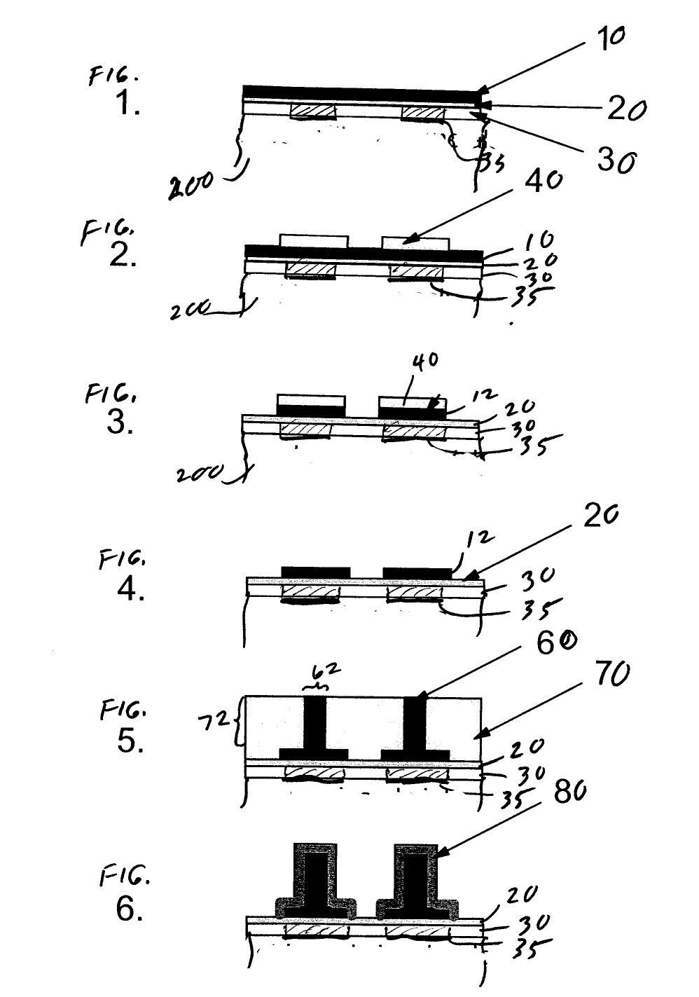

FIG. 1 shows a top area of an integrated circuit with unpatterned layers. At the bottom, box 200 represents the electronic structure, e.g. an integrated circuit that is to be attached by the contacts to be formed. Layer 30 is a dielectric layer, e.g. polyimide that encapsulates the structure insulating the interconnections and blocking the penetration of moisture and other undesirable chemicals.

Boxes 35 represent schematically vias extending up from interconnections not shown through the polyimide. The contacts on the top of the structure will be made to these vias.

Layer 20 is a barrier and/or adhesion metallurgy layer. For example, TiW, Ti, TaN and other materials known to those skilled in the art are used to block penetration of the contact materials, e.g. copper and/or to promote adhesion between the contact materials and the interconnect materials, (typically aluminum alloys).

Layer 10 is a seed layer that promotes deposition and plating of the material for the pins to be formed. As the contacts become smaller, the current capacity of the contact materials becomes more important, so that copper is preferred is the material.

FIG. 2 shows the same area after patterning a layer of photoresist 40. Resist 40 has been deposited with a conventional method and patterned to define pad areas above contacts 35.

FIG. 3 shows the result of etching through the seed layers, using an etchant that does not attack the underlying barrier layer 20. Illustratively, an electroetch employing appropriate currents and electrolyte as established by Pourbaix diagrams is suitable for this step.

FIG. 4 shows the structure after stripping the photoresist, leaving pads 12 that will serve as the base for a further structure. Pads 12 are in electrical contact with contacts 35, to carry power and signals into the devices contained within box 200.

FIG. 5 shows the result of a series of steps in which a thick layer of photoresist 70, e.g. up to 100 microns thick has been put down and patterned such that the resist polymerizes outside the areas where pins are to be formed and is dissolved in a conventional development step. The subsequent apertures have the dimension of pins 60. Typically, the diameter of the pins is indicated by bracket 62 and is about 25 microns. The thickness of the aperture in the resist is indicated by bracket 72. The aspect ratio of the apertures is preferably in the range of three to one. Pins 60 are formed by electroplating copper in the apertures, using the interconnect structure attached to contacts 35 as the current path, to form pins 60.

Advantageously, the copper in the pins 60 is bonded directly to the copper in seed layer 10. In prior art structures, the pins were attached by solder fillets, which had the drawback of having direct contact between the copper and the solder.

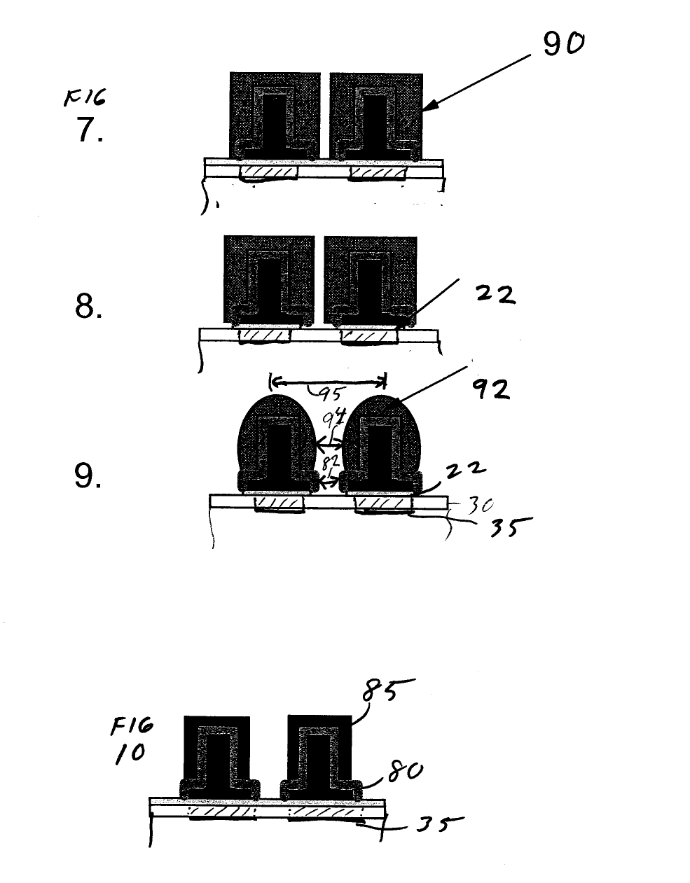

FIG. 6 shows the result of plating a barrier metal on the copper. Illustratively, the barrier metal is nickel, which effectively confines the copper and prevents the formation of undesired compounds by reaction of the copper with a constituent of the solder, such as tin. The plating process inherently forms a barrier layer over all exposed surfaces—the vertical edge of pads 12, the top of the pads and the top and sides of the copper pins 60.

FIG. 7 shows the result of plating a layer of solder, before reflow. Solder 90 is shown as extending over the nickel barrier layer and down to the adhesion layer 20. Advantageously, the solder composition is chosen to preferentially plate to the barrier layer with respect to the material of the adhesion layer such that the solder does not adhere to layer 20. This has the beneficial consequence that there is a clean separation between adjacent solder structures. If the solder did adhere well to layer 20, it would have formed a coating all over the surface of layer 20 that would have to be removed to prevent shorting the contacts.

FIG. 8 shows the result of etching the adhesion layer 20. Illustratively, the etchant does not attack the solder to any significant degree, but does attack and remove the relatively thin (commonly less than 5000 angstroms) layer 20. It can be seen in the figure that the etching process has been continued with an overetch that undercuts the solder 90 and reaches the barrier layer.

FIG. 9 shows the result of reflowing the solder in a conventional oven. The surface tension of the solder has formed the structure into a smooth curve suitable for the C4 process. Arrow 82 illustrates a typical, but not exclusive, tolerance distance between closest parts of the barrier layer of 50 microns and arrow 94 indicates a corresponding tolerance for the closest approach of solder 90 of 50 microns. Arrow 95 at the top, illustrates the design pitch, illustratively 100 microns, that dictates the thickness of the various layers to achieve the tolerances 82 and 94.

As dimensions shrink, the thickness of the various layers will be adjusted accordingly.

FIG. 10 shows a step in an alternative embodiment, in which a wetting layer 85, illustratively 0.5 microns of Cu or Au has been plated to improve adhesion between the nickel barrier and the solder. Since the copper post underneath the nickel is relatively thick and the copper atop the nickel acts to reduce the chemical potential gradient across the barrier the outer copper layer can be regarded as a sacrificial layer in this embodiment.

Layer 85 will be plated or deposited after the step of forming the barrier layer and before the step of depositing the solder.

The following summarizes the sequence of process steps.

Process Sequence

1. Starting structure: integrated circuit with terminals below apertures in an insulator (polyimide); seed metal stack.

2. pattern photoresist to define pin base.

3. etch seed layers, leaving pads.

4. pattern thick photoresist for pins.

5. plate pins in apertures.

6. strip photoresist.

7. plate barrier material on pins and pad.

8. plate barrier selectively to solder.

9. etch seed stack selective to solder and barrier.

10. reflow solder.

Those skilled in the art will readily be able to adapt the foregoing example to other circumstances. For example, the terms forming, depositing and plating are not meant to be exclusive and are meant to include alternative methods, such as sputtering, chemical vapor deposition, etc. to achieve the same or similar result.

While the invention has been described in terms of a single preferred embodiment, those skilled in the art will recognize that the invention can be practiced in various versions within the spirit and scope of the following claims.

1. A method of forming electrical connection members on an electrical structure comprising the steps of:
providing an electrical structure with a set of contacts;
forming at least one interface layer adhering to said set of contacts;
patterning said interface layer to form a set of pads disposed over said set of contacts;
depositing and lithographically patterning a layer of photoresist with a set of apertures over said set of pads;
forming a set of conductive pins adhering directly to said pad;
forming a barrier layer adhering to all exposed surfaces of said set of pins;
forming a layer of solder surrounding the barrier layer; and
reflowing the layer of solder.

2. A method according to claim 1, in which the material of the barrier layer blocks passage of material from the pins, thereby preventing the material from the pins from reacting with a constituent of the solder.

3. A method according to claim 1, in which the interface layer comprises a layer of adhesion material and a seed layer.

4. A method according to claim 2, in which the interface layer comprises a layer of adhesion material and a seed layer.

5. A method according to claim 1, in which the interface layer includes material selected from the group comprising TiW, Ti, Ta, Cr and TaN.

6. A method according to claim 2, in which the interface layer includes material selected from the group comprising TiW, Ti, Ta, Cr and TaN.

7. A method according to claim 3, in which the interface layer includes material selected from the group comprising TiW, Ti, Ta, Cr and TaN.

8. A method according to claim 4, in which the interface layer includes material selected from the group comprising TiW, Ti, Ta, Cr and TaN.

9. A method according to claim 1, in which the pins are formed by electroplating material into the apertures in the photoresist.

10. A method according to claim 1, in which the pins are plated with a wetting layer before the step of forming a layer of solder.

11. A method according to claim 10, in which the material of the barrier layer blocks passage of material from the pins, thereby preventing the material from the pins from reacting with a constituent of the solder.

12. A method according to claim 10, in which the interface layer comprises a layer of adhesion material and a seed layer.

13. A method according to claim 11, in which the interface layer comprises a layer of adhesion material and a seed layer.

14. An electrical structure containing electrical connection members adapted for connecting to another electrical structure comprising:
a first set of contacts in an electrical structure;
at least one interface layer adhering to said set of contacts;
a set of pads disposed over said set of contacts and including said interface layer;
a set of conductive pins adhering directly to said pads;
a barrier layer adhering to all exposed surfaces of said set of pins; and
a layer of solder surrounding the barrier layer.

15. A structure according to claim 14, in which the material of the barrier layer blocks passage of material from the pins, thereby preventing the material from the pins from reacting with a constituent of the solder.

16. A structure according to claim 14, in which the interface layer comprises a layer of adhesion material and a seed layer.

17. A structure according to claim 15, in which the interface layer comprises a layer of adhesion material and a seed layer.

18. A structure according to claim 14, in which the interface layer includes material selected from the group comprising TiW, Ti, Ta, Cr and TaN.

19. A structure according to claim 15, in which the interface layer includes material selected from the group comprising TiW, Ti, Ta, Cr and TaN.

20. A structure according to claim 14, in which a wetting layer selected from the group comprising Cu and Au is formed on the barrier layer.
